(19) United States
(12) Patent Application Publication
(10) Pub. No.: US 2009/0009281 A1
(43) Pub. Date: Jan. 8, 2009

(54) Fuse element and manufacturing method thereof

(75) Inventors: Chung-Hsiung Wang, Hsinchu (TW); Yu-Liang Song, Suzhou city (CN); Qing-Feng Song, Wujiang City (CN); Yu-Qiao Li, Heng Yan city (CN); Jian-Da Qiu, Suzhou city (CN); Meng Liu, Nanjing city (CN)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CYNTEC COMPANY

(21) Appl. No.: 11/825,488

(22) Filed: Jul. 6, 2007

(51) Int. Cl. H01H 85/04; H01L 21/44

(52) U.S. Cl. 337/297; 438/601; 257/E21.476; 337/66

(57) ABSTRACT

A fuse element comprises a substrate having a top surface, a bottom surface opposite to said top surface, and side surfaces, a heat insulation layer including a first surface and a second surface opposite to said first surface, said first surface of said heat insulation layer disposed on said top surface of said substrate, and said second surface having a surface roughness, a protective layer disposed above said heat insulation layer, and a fuse layer disposed between said heat insulation layer and said protective layer.

### BACKGROUND OF THE INVENTION

1. Field of the Invention

This invention relates generally to a device configuration and manufacturing method for providing a fuse element. More particularly, this invention relates to an improved device configuration and manufacturing method for providing a fuse element by using resin coated copper (RCC) foil.

2. Description of the Prior Art

Even though there are many types of fuse elements implemented as over current protection, there are still technical limitations and difficulties as now available in the marketplace to provide fuse elements configured a micro-chip. Specifically, there are basically following types of fuse elements configured as chips.

The first type of fuse elements is fuse elements that are supported on a ceramic substrate. This type of fuse elements has the benefit of reliable operation at a higher operation because the ceramic substrate can sustain higher temperature. However, the thermal conductivity of the ceramic substrate is generally in the range of 8-10 W/m° K. while the thermal conductivity of glass is 2-4 W/m° K. and polymer substrates generally have a thermal conductivity of 0.2-0.5 W/m° K. Thus, compared with glass and polymer substrates, the ceramic substrate has a relatively higher thermal conductivity. Due to this higher thermal conductivity, a fuse element supported on a ceramic substrate often requires longer time to reach a fuse temperature to break the circuit for over-current protection.

Another type of fuse elements are produced with thick film technologies that are generally manufactured on a glass substrate by using thick film processes. The thick film processes are able to precisely pattern the fuse with accurately controllable resistance at room temperature thus provide better protection with well controlled fuse-breaking condition that is repeatable. The glass substrate further provides another benefit that the fuse breaking action would not lead to sparks, flame or burning, therefore, there no concerns of burning or smoke damages to nearby circuits or components. The thick film type of fuse elements further has adequate capacity to sustain higher current to pass through. However, similar to the first type of fuse elements, longer time is required to activate a fuse breaking action due to a higher thermal conductivity of the glass substrate. It is often required to use a thicker layer for fuse thus causes higher resistance and higher power consumption.

For the purpose of inducing a faster fuse breaking action, a fiberglass may be implemented that has a lower thermal conductivity. Many kinds of printed circuit boards (PCB) are available at lower cost to reduce the production costs. However, such substrate lacks characteristics of high temperature and high current reliabilities that are often required for many applications of over-current protections. The scopes of fuse elements using fiberglass as supporting substrates are therefore greatly limited.

In order to overcome the above discussed difficulties, another type of fuse elements is manufactured with a thin film technology on aluminum oxide (Al₂O₃) substrate. A laser scribing process can be conveniently carried out to form the fuse chips thus significantly speed up the production cycles for manufacturing such fuse chips. However, such fuse elements are conventionally configured with an aluminum oxide substrate cover with a polymer layer to function as a heat insulation layer. Since the polymer layer has a low thermal conductivity, there is a benefit of quick fuse breaking action for over-current protection. However, similar to the fuse elements that supported on the fiberglass substrates, the polymer layer is not stable in a high temperature. Therefore, the conventional thin-film fuse elements supported on the aluminum oxide substrate have limited scope applications due to the limited capacity to sustain high temperature and high current operations. Furthermore, a fuse layer and the substrate are not securely adhered to the heat insulation layer due to both surfaces of the heat insulation layer surface are formed smooth surfaces.

Therefore, a need still exists in the art of design and manufacture of fuse element to provide a novel and improved device configuration and manufacturing method to resolve the difficulties.

### SUMMARY OF THE PRESENT INVENTION

It is therefore an aspect of the present invention to provide a fuse element and a manufacturing method of the fuse element to sustain a high current and high temperature operation without the limitation of slower fuse breaking reaction as that generally encountered in the above-discussed conventional techniques such that the difficulties and limitations can be overcome.

Specifically, in one aspect of this invention, the surface roughness of the second surface of the heat insulation layer can increase the adhesion of the resin layer to the substrate, to the first seed layer, and to the fuse layer.

It is another aspect of this invention, the fuse element is implemented by laminating a substrate with a heat insulation layer having a good insulation characteristics and high glass transition temperature (Tg) above 150° Celsius to sustain high temperature operation and also to reduce the thermal conductivity to a range of approximately 0.2 W/m° K. In an exemplary embodiment, a top surface of the substrate insulated with the resin layer having a thermal conductivity of between 1.0 W/m° K. and 0.1 W/m° K.

It is another aspect of this invention that a copper foil laminated to the resin layer to laminated to the substrate is processed to have a roughness surface on both the copper surface and a top surface of the substrate such that secure and strong adhesion between the copper foil and the resin layer to the substrate are achieved to produce reliable fuse element that can sustain long term high temperature and high current operations. Furthermore, the copper foil is implemented as electrode terminal to achieve low resistance current conduction.

Another aspect of this invention is the application of the alloys of Au/Pt, Au/Co or Au/Pd as buffer layer to diffuse rapidly to an acceleration layer composed of tin such that the rate of fuse breaking can be well controlled with relatively increased amount of conducting current through the fuse element for broader scopes of over-current protection.

This invention discloses a method for manufacturing a fuse element by laminating a copper foil with a resin layer attached on a top surface of a substrate where the resin layer has a high glass transition temperature above 150° Celsius. The method further includes a step of carrying out a roughening process to roughen the top surface of the substrate and a bottom surface of the copper foil to increase the adhesion of the resin layer to the substrate and to the copper foil. Furthermore, the method further includes a step of carrying out a roughening process to roughen a surface of the resin layer to increase the adhesion of the resin layer to the substrate, to a first seed layer, and a fuse layer.

These and other objects and advantages of the present invention will no doubt become obvious to those of ordinary skill in the art after having read the following detailed description of the preferred embodiment which is illustrated in the various drawing figures.

### BRIEF DESCRIPTION OF THE DRAWINGS

FIG. 1 is a cross sectional view of a fuse element according to the present invention.

FIGS. 2A to 2G are a series of cross sectional views for showing layer structures and processes for manufacturing the fuse element according to the present invention.

### DETAILED DESCRIPTION OF THE PREFERRED EMBODIMENT

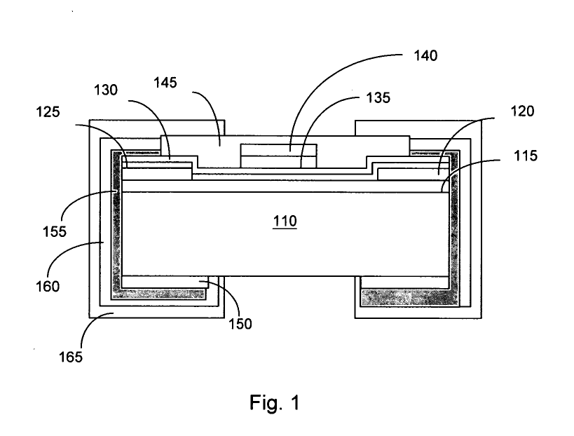

Referring to FIG. 1, a fuse element 100 according to the present invention comprises a substrate 110, a heat insulation layer 115, a pair of copper terminal 120, a first seed layer 125, a fuse layer 130, a buffer layer 135, an accelerated layer 140, a protective layer 145, a bottom terminal layer 150, a second seed layer 155, and side terminal layers 160 and 165. The protective layer 145 is disposed above the heat insulation layer 115. The fuse layer 130 is disposed between the heat insulation layer 115 and the protective layer 145. The fuse element is manufactured with a thin film technology.

The fuse element 100 begins with the substrate 110 for supporting the other elements of the fuse element 100. In the embodiment, the material of the substrate 110 is an aluminum oxide (Al₂O₃). Other material for the substrate 110 includes, but not limited to, glass. The substrate 110 includes a top surface 1101, a bottom surface 1102 opposite to the top surface 1101, and side surfaces 1103.

The heat insulation layer 115 includes a first surface 1151 and a second surface 1152 opposite to the first surface 1151. The second surface 1152 has a surface roughness in the range 300 nm to 400 nm. The first surface 1151 of the heat insulation layer 115 is disposed on the top surface 1102 of the substrate 110. The heat insulation layer 115 is a resin having a high glass transition temperature (Tg) above 150° Celsius and a thermal conductivity of between 1.0 W/m° K. and 0.1 W/m° K. The surface roughness of the second surface 1152 can increase the adhesion of the resin layer to the substrate 110, to the first seed layer 125, and to the fuse layer 130.

The copper terminal 120 is disposed at two opposite ends of the second surface 1152 of the heat insulation layer 115 to achieve low resistance current conduction. The other purpose of the copper terminal 120 is to increase the area that is electrically connected with the side terminal layers 160 and 165 due to the thickness of the fuse layer 130 is very low.

The first seed layer 125, for example, but not limited to, nickel (Ni) or NiCr, is disposed on the copper terminals 120 and the second surface 1152 of the heat insulation layer 115. The fuse layer 130 composed of copper (Cu) or copper-tin (CuSn) alloy is disposed on the first seed layer 125. The fuse layer 130 is adapted for conducting a current therethrough. The buffer layer 135 composed of Au/Pd, Au/Pt or Au/Co is disposed on the fuse layer 130 and the accelerated layer 140 composed of tin (Sn) is disposed on the buffer layer 135. The buffer layer 135 is disposed between the accelerated layer 140 and the fuse layer 130. The application of the alloys of Au/Pt, Au/Co or Au/Pd as buffer layer 135 to diffuse rapidly to an acceleration layer 140 such that the rate of fuse breaking can be well controlled with relatively increased amount of conducting current through the fuse element for broader scopes of over-current protection.

The protective layer 145 is disposed over the buffer layer 135 and the acceleration layer 140. The protective layer 145 can be includes a Polymer, or a combination of a first protective layer (not shown) composed of epoxy and a second protective layer (not shown) composed of polyimide (PI). The first protective layer is disposed between the acceleration layer 140 and the second protective layer. When a current is conducting over the fuse layer 130, the temperature starts to increase. The acceleration layer 140 will diffuse to the fuse layer 130 thus forming an alloy. While the melting alloy spill out, the second protective layer composed of PI can stop the residue of melting alloy to stay inside of the second protective layer, since the PI has characteristics, such as high melting point, flexibility, not easy to flame, low moisture absorption, and excellent thermal prosperity.

The bottom terminal layer 150 composed of NiCr/NiCu is formed on the bottom surface of the substrate 110 followed by the process of formation a side terminal. The second seed layer 155 composed of NiCr/NiCu wraps around the side surfaces 1103 of the substrate 110. Then the side terminal layers 160 and 165 composed of Cu/Ni/Sn wraps around the side surfaces 1103 of the substrate 110 and are disposed over the second seed layer 155. In the embodiment, the second seed layer 155, the side terminal layer 160, and the side terminal layer 165 are copper layer, Ni layer, and Sn layer respectively. The copper layer is formed to lower the resistance of the edge terminal. Since the fuse element is copper, and different thickness of the fuse layer is used for different currents, it is required to reduce the resistance of the edge terminal in order prevent the situation that a low current would limit the fuse action if the resistance of the edge terminal limits the current passes through the fuse element. The Ni layer functions as barrier layer and the Sn layer is applied as a soldering layer for conveniently soldering the circuits to be protected by the fuse element.

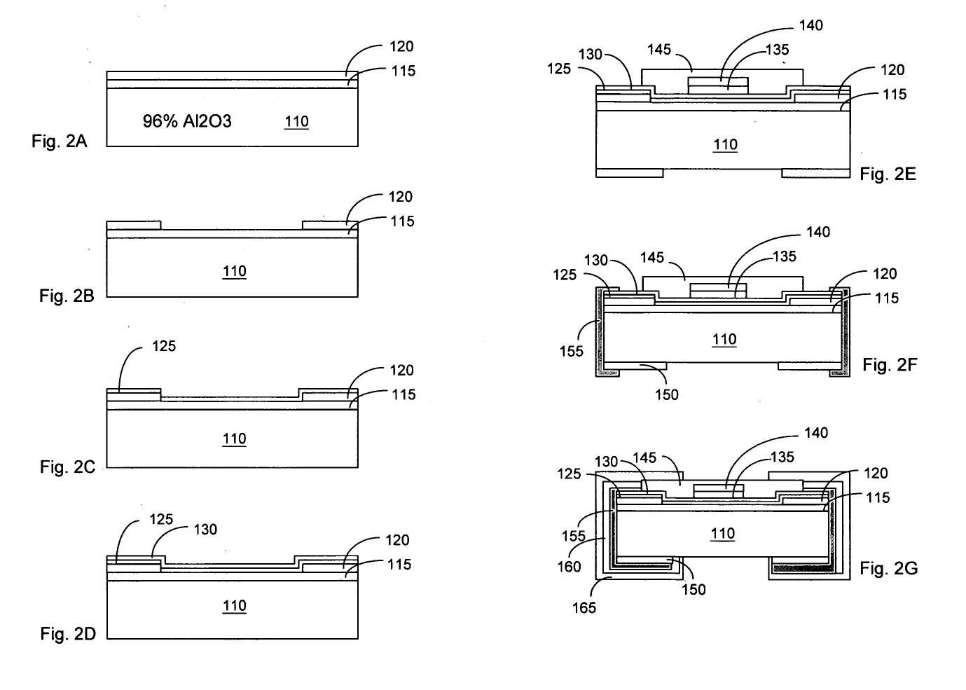

Referring to FIGS. 2A to 2G for a series of cross sectional views to illustrate the manufacturing processes of the fuse element 100 as shown in FIG. 1. In FIG. 2A, a roughening process is carried out to roughen a top surface of a substrate and a bottom surface of a copper foil, and then the substrate lamination process is carried out to laminate the substrate 110 to a special copper foil, i.e., a resin coated copper foil (RCC) that includes a copper foil 120′ coated with a resin layer 115′. The resin layer 115′ coated copper foil 120′ is a one-side resin that is coated onto the copper foil 120′ with a thickness of the resin ranging between 40 to 90 μm. The resin layer 115′ may be composed of epoxy. When a heat is applied to the RCC over a temperature over a Tg where Tg stands glass transition temperature for the resin layer 115′ is cured and generated a strong and secure bonding to the substrate 110 and the copper foil 120′. In order to more securely attach the RCC to the laminated substrate 110, the substrate lamination process is carried out in a low pressure condition that bubbles in the resin layer 115′ is eliminated when the pressure and cure temperature is applied to the RCC adhering to the substrate 110. Furthermore, in order to assure secure adhesion of the copper foil 120′ to the substrate 110 through the resin layer 115′, the surface of the copper foil 120′ and the surface of the substrate 110 are roughened such that the interfacing surfaces to the resin layer 115′ can be securely bonded together. The surface roughness of the substrate 110 is around 500 nm±100 nm, the surface roughness of the copper foil 120′ is around 310±50 nm, and the surface roughness of resin layer 115′ after removed of copper is around 350±50 nm.

In FIG. 2B, an etch process is carried out by applying a photolithographic process by first spin coating the photo resist followed by lithographic exposure and etching to etch out a central portion of the copper foil 120′ to expose the second surface 1152 of the resin layer and keeping two segments to serve as the copper terminals 120 that are electrode terminals of the fuse circuit with low resistance. And the resin layer 115′ serves as the heat insulation layer 115. The photo resist is not shown. In FIG. 2C, a first seed layer 125 composed of Ni or NiCr is sputtered or lithographically onto a top surface of the copper terminals 120 and the second surface 1152 of the heat insulation layer 115. The thickness of the first seed layer 125 is approximately 1000±400 Angstroms. The purpose of the first seed layer 125 is to increase the layer thickness of plating of conductive layer due to the fact that the thickness of the copper foil is very low. The plating operation is enhanced with the application of the first seed layer 125. Since the surface of the copper foil 120′ is roughened, the surface of the resin layer 115′ that is exposed after etching off the copper foil 120′ from the central area also has a roughness surface and the first seed layer 125 is securely adhered to the copper terminals 120 and also to the heat insulation layer 115.

In FIG. 2D, a forming a fuse layer 130 process is carried out to form copper or copper-tin layer onto a top surface of the first seed layer 125 by electroplating or sputtering. The thickness of the fuse layer 130 depends on the fusing current that is dependent on the application of this fuse element. The fuse layer 130 is first sputtered or electroplated and then patterned by applying a photolithographic etching and patterning process.

In FIG. 2E, a buffer layer 135 composed of Au/Pd, Au/Pt or Au/Co is electroplated first and an acceleration layer 140 composed of tin (Sn) is electroplated on a top surface of the buffer layer 130. A protective layer 145 composed of Polymer, or a combination of an epoxy and a polyimide is printed over the fuse circuit of the buffer layer, the acceleration layer 140 and a portion of the fuse layer 130 and the first seed layer 125. The buffer layer 135 and the acceleration layer 140 serve special functions. Specifically, when a current is conducting over the fuse layer 130, the temperature starts to increase. The tin metal of the acceleration layer 140 will diffuse to the fuse layer 130 thus forming an alloy. As the tin-copper alloy is formed, and the composition of the fuse layer is changed, a different melting point is generated thus causing an acceleration of the breaking of the fuse layer. However, in certain application, it may not be desirable for the fuse to break with an acceleration rate, therefore, the acceleration of the fuse action may be controlled by forming a buffer layer 135 to control the timing of fuse-breaking action when an over-current situation occurs.

A bottom terminal layer 150 is sputtered onto the bottom surface of the substrate 110 and composed of NiCr/NiCu having a thickness approximately 500±300 Angstroms. The fuse elements supported on the substrate 110 is then laser scribed and stacked to tooling for NiCr/NiCu sputtering as shown in FIG. 2F, where a wrapping-around the second seed layer 155 composed of NiCr or Ni/Cu is sputtered over the side surfaces as a sidewall wrapping around layer. In FIG. 2G, side terminal layers 160 and 165 are formed with electroplated Cu/Ni/Sn to complete the manufacturing processes of the fuse element 100 as shown in FIG. 1.

The fuse element 100 as disclosed in this invention has special structural features. The first structural feature is the use of an aluminum oxide (Al₂O₃) as the supporting substrate. The aluminum oxide substrate provides a benefit of reliable operation at high temperature. Moreover, because of the fact that it is more convenient to apply existing technologies and manufacturing processes on the aluminum oxide, the use of aluminum oxide further reduce the production cost. However, the substrate employed in this invention, e.g., an aluminum oxide, is a heat dissipation substrate. For the purpose of manufacturing a fuse element, a heat dissipation substrate such as the aluminum oxide is generally not suitable for application for supporting the fuse element due to the fact that a fuse element require to accumulate heat quickly to break the fuse layer when an over-current even occurs. For this reason, a thin layer of insulation, i.e., a coated resin layer as a heat insulation material is applied to reduce the heat dissipation from the substrate. Another structural feature of this invention is the surface roughness of the copper foil that provide secure adhesion to the coated resin layer and thus provide reliable fuse elements with secure adhesion to the substrate 110 and also to the first seed layer 125.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

We claim:

1. A fuse element, comprising:
a substrate having a top surface, a bottom surface opposite to said top surface, and side surfaces;
a heat insulation layer including a first surface and a second surface opposite to said first surface, said first surface of said heat insulation layer disposed on said top surface of said substrate, and said second surface having a surface roughness;
a protective layer disposed above said heat insulation layer; and
a fuse layer disposed between said heat insulation layer and said protective layer.

2. The fuse element of claim 1, wherein said heat insulation layer comprises resin having a high glass transition temperature above 150° C.

3. The fuse element of claim 1, wherein said heat insulation layer comprises resin having a thermal conductivity of between 1.0 W/m° K. and 0.1 W/m° K.

4. The fuse element of claim 1, wherein material of said substrate is an aluminum oxide.

5. The fuse element of claim 1, wherein said fuse layer comprise of copper or copper-tin alloy for conducting a current therethrough.

6. The fuse element of claim 1, further comprising a pair of copper terminal disposed at two opposite ends of said second surface of said heat insulation layer, and said fuse layer disposed between said copper terminal and said protective layer.

7. The fuse element of claim 6, further comprising a first seed layer composed of Ni or NiCr disposed on said copper terminals and said second surface of said heat insulation layer, and said fuse layer disposed on said first seed layer.

8. The fuse element of claim 1, further comprising a buffer layer composed of Au/Pd, Au/Pt or Au/Co disposed on said fuse layer and an acceleration layer composed of Sn disposed on said buffer layer.

9. The fuse element of claim 1, wherein said protective layer comprises a Polymer.

10. The fuse element of claim 1, wherein said protective layer comprises a first protective layer and a second protective layer composed of polyimide, and said first protective layer is disposed between said fuse layer and said second protective layer.

11. The fuse element of claim 1, further comprising a bottom terminal layer composed of NiCr/NiCu and disposed on said bottom surface of said substrate, and side terminal layers composed of Cu/Ni/Sn wrapping around said side surfaces of said substrate.

12. The fuse element of claim 11, further comprising:
a seed layer composed of NiCr/NiCu wrapping around said side surfaces of said substrate and disposed between said side terminal layers and said side surfaces of said substrate.

13. A method for manufacturing a fuse element comprising the steps of:
forming a resin layer to a substrate;
roughening a second surface of said resin layer;
forming a fuse layer onto said second surface of said resin layer; and
forming a protective layer over said fuse layer.

14. The method of claim 13, wherein said step of roughening a second surface of said resin layer comprises:
roughening a bottom surface of a copper foil;
laminating a top surface of a substrate to said bottom surface of said copper foil through said resin layer; and
etching out of a central portion of said copper foil to expose said second surface of said resin layer.
